(19) United States
(12) Patent Application Publication
(10) Pub. No.: US 2026/0214850 A1
(43) Pub. Date: Jul. 23, 2026

(54) DROPLET-BASED COOLING ASSEMBLIES

(71) Applicant: Toyota Motor Engineering & Manufacturing North America, Inc., Plano, TX (US)

(72) Inventor: Shailesh Joshi, Ann Arbor, MI (US)

(73) Assignee: Toyota Motor Engineering & Manufacturing North America, Inc., Plano, TX (US)

(21) Appl. No.: 19/033,001

(22) Filed: Jan. 21, 2025

(51) Int. Cl. H05K 7/20

(52) U.S. Cl. CPC H05K 7/20327

(57) ABSTRACT

In one embodiment, a cooling assembly includes a first hydrophilic surface and a second hydrophilic surface, an array of liquid inlets within one of the first hydrophilic surface and the second hydrophilic surface operable to provide a liquid to form an array of droplets between the first hydrophilic surface and the second hydrophilic surface, at least one liquid channel fluidly coupled to the array of liquid inlets for providing liquid to the array of liquid inlets, one or more vapor outlets within the one of the first hydrophilic surface and the second hydrophilic surface operable to receive vapor from between the first hydrophilic surface and the second hydrophilic surface, and a vapor channel fluidly coupled to the array of vapor outlets for receiving the vapor from the array of vapor outlets.

### BACKGROUND

Two-phase cooling technologies may be used to remove extreme heat fluxes, such as heat fluxes generated by power electronic devices. The technology can be applied for both active and passive two-phase cooling such as pumped two phase systems, vapor chamber heat spreader, and the like.

The issue with two phase cooling technologies is bubble generation that causes early dryout (maximum heat flux) but also increases the pressure drop of the system. In addition, porous structures can be used to improve boiling performance, but the cost and reliability need to be carefully evaluated for long term operation. Another mode of two-phase cooling is the use of evaporative cooling where the liquid is turned into vapor while minimizing the bubble generation issue; however, some amount of flooding is unavoidable that causes liquid-vapor interaction causing temperature oscillations and hence lower performance.

### BRIEF SUMMARY

In one embodiment, a cooling assembly includes a first hydrophilic surface and a second hydrophilic surface, an array of liquid inlets within one of the first hydrophilic surface and the second hydrophilic surface operable to provide a liquid to form an array of droplets between the first hydrophilic surface and the second hydrophilic surface, at least one liquid channel fluidly coupled to the array of liquid inlets for providing liquid to the array of liquid inlets, one or more vapor outlets within the one of the first hydrophilic surface and the second hydrophilic surface operable to receive vapor from between the first hydrophilic surface and the second hydrophilic surface, and a vapor channel fluidly coupled to the array of vapor outlets for receiving the vapor from the array of vapor outlets.

In another embodiment, a cooling assembly includes a first hydrophilic surface, a plurality of porous strips provided on the first hydrophilic surface, a second hydrophilic surface provided proximate a surface of the plurality of porous strips, an array of hydrophobic regions on at least the second hydrophilic surface, a liquid inlet port operable to provide liquid between in the first hydrophilic surface and the second hydrophilic surface in a flow path that is transverse to the plurality of porous strips, and a plurality array of vapor outlets within the second hydrophilic surface. The cooling assembly also includes a vapor outlet channel fluidly coupled to the array of vapor outlets, where the array of hydrophobic regions cause an array of droplets to form between the first hydrophilic surface and the second hydrophilic surface.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a perspective view of an example cooling assembly according to one or more embodiments described and illustrated herein.

FIG. 2 illustrates a cross-sectional view of an example cooling assembly according to one or more embodiments described and illustrated herein.

FIG. 3 illustrates a top view of the example cooling assembly of FIG. 2 according to one or more embodiments described and illustrated herein.

FIG. 4A illustrates a top view of another example of a cooling assembly according to one or more embodiments described and illustrated herein.

FIG. 4B illustrates a partial perspective view of the cooling assembly of FIG. 4A according to one or more embodiments described and illustrated herein.

FIG. 5 illustrates a cross-sectional view of the cooling assembly of FIG. 4A according to one or more embodiments described and illustrated herein.

FIG. 6 illustrates a cross-sectional view of another cooling assembly according to one or more embodiments described and illustrated herein.

FIG. 7 illustrates a cross-sectional view of another cooling assembly according to one or more embodiments described and illustrated herein.

FIG. 8 illustrates a cross-sectional view of another cooling assembly according to one or more embodiments described and illustrated herein.

### DETAILED DESCRIPTION

Embodiments of the present disclosure are directed to evaporative cooling assemblies that utilize to hydrophilic surfaces to maintain an array of liquid droplets. Embodiments avoid undesirable early dry out and increased pressure drops by utilizing a droplet based microfluidic cooler. The cooling assemblies described herein rely on a combination of liquid substrate properties (hydrophilic surfaces) while taking advantage of the extreme heat transfer coefficient from thin-film evaporation from the droplet surface. Another feature is a unique confinement of an array of micro droplets between two surfaces to remove high heat fluxes but also utilize the droplet dynamics to supply liquid.

More particularly, in embodiments a plurality of liquid inlets introduce liquid into a vapor chamber defined by the two hydrophilic surfaces. One or more vapor outlets are provided to remove vapor due to a phase change of the droplets caused by heat from the heat generating device, such as an electronics device. The liquid may be introduced into the vapor chamber and a top feed configuration where the liquid flows down into the vapor chamber, or a side feed configuration where the liquid travels through micro-channels that is deposited on the hydrophilic surface. The cooling assemblies of the present disclosure may be active in that a pump is utilized to pump cooled liquid into the vapor chamber and a condenser is used to convert vapor into a liquid that is then returned to the vapor chamber by the pump. The cooling assemblies of the present disclosure may also be passive in that the vapor chamber is completely enclosed and the vapor is condensed within the vapor chamber itself to continuously supply the droplets. Hydrophobic regions may be patterned on one or more of the hydrophilic surfaces to define the location of the droplets as well as to provide a return path of liquid in the passive cooling embodiments. Additionally, flexures may be provided that adjust a gap H of the vapor chamber to continuously tune the performance of the cooling assembly.

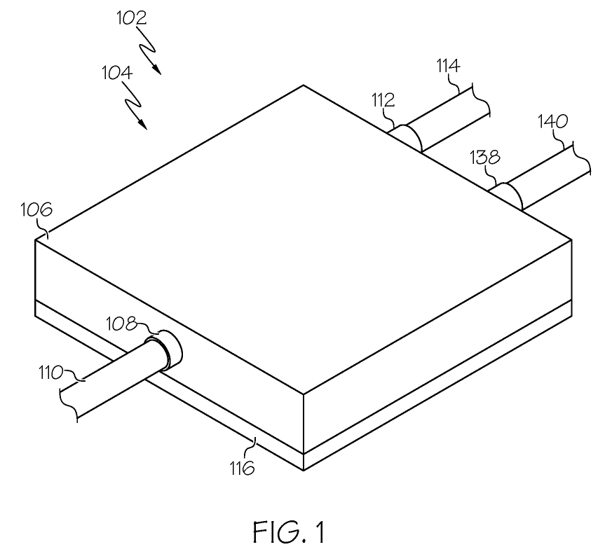

Referring now to FIG. 1, an example electronics assembly 102 is illustrated in a perspective view. The example electronics assembly 102 includes an electronic device 116 coupled to a cooling assembly 104. The cooling assembly 104 is operable to remove heat generated by the electronic device 116, or in some cases multiple electronic devices 116. The cooling assembly 104 ensures that the electronic device 116 operates below its maximum operating temperature.

Embodiments are not limited to any electronic device 116 and, in some cases, the electronic device 116 is a heat generating component that is not an electronic device. Thus, the cooling assembly 104 may be used to cool any type of heat generating component.

Non-limiting example electronic devices 116 include metal-oxide-semiconductor field-effect transistors (MOSFETs), insulated-gate bipolar transistors (IGBTs), thyristors, power transistors, power diodes, and the like. As a non-limiting example, the electronic devices 116 described herein may be components of an inverter circuit of an electrified vehicle (e.g., a fully electric vehicle, a hybrid vehicle, or a plug-in hybrid vehicle) to convert direct current (DC) voltage to alternating current (AC) for powering an electric motor of the electrified vehicle. It should be understood that the electronics assemblies 102 described herein may be utilized in other applications as well.

The example cooling assembly 104 includes a housing 106 having fluid inlet port 108 for providing a cooling liquid through an inlet line 110 into an enclosure defined by the housing 106. The housing 106 also includes a liquid outlet port 112 for removing bypass liquid through a liquid outlet line 114, and a vapor outlet port 138 for removing vapor through a vapor outlet line 140. It should be understood that more than one liquid outlet port 112 and more than one vapor outlet port 138 may be provided. Further, in some embodiments the liquid outlet port 112 and the vapor outlet port 138 may be combined into a single outlet port that moves both bypass liquid and vapor from the housing 106.

Embodiments of the present disclosure use controlled droplets of cooling liquid in a two-phase cooling application. By controlling the distribution and size of droplets within the housing 106, improved cooling efficiency is achieved.

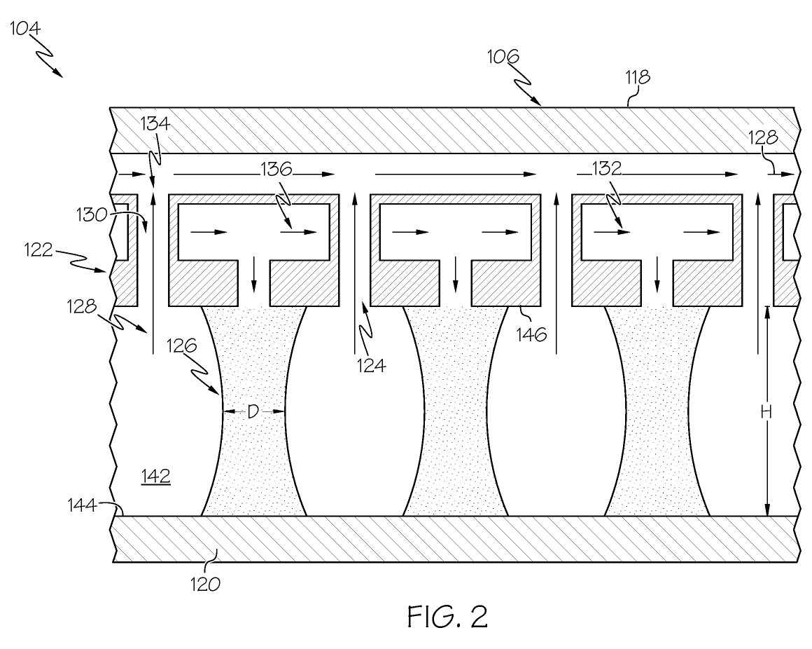

Referring now to FIG. 2, a cross-sectional view of an example cooling assembly 104 is provided. The housing 106 defines a lower housing 120 that receives heat flux from a heat generating component, such as an electronic device 116, for example. The housing 106 also defines an upper housing 118 along with side walls (not shown) that form a vapor chamber 142 within the housing 106. A manifold 122 is disposed within the vapor chamber 142 and is operative to both introduce droplets 126 into the vapor chamber 142 as well as remove vapor 128 from the vapor chamber 142.

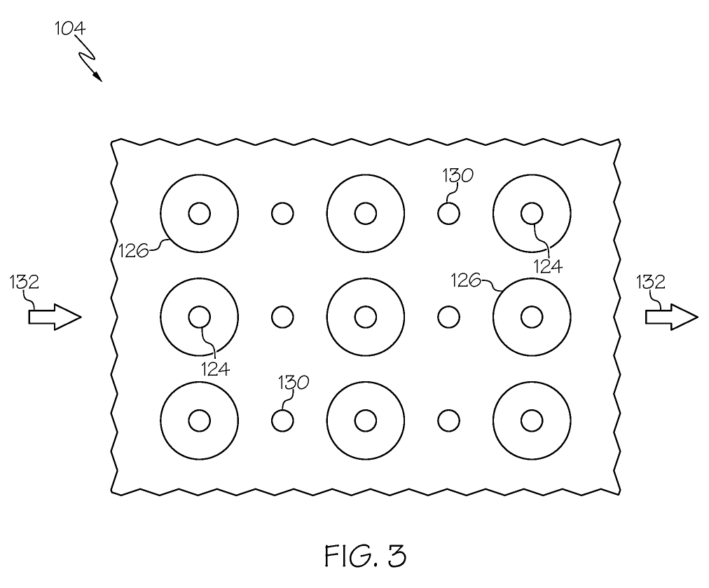

The example cooling assembly 104 of FIG. 2 is a top-feed structure whereby liquid is introduced into the vapor chamber 142 to form droplets 126. FIG. 3 schematically illustrates a top-view of the manifold 122 of FIG. 2. The manifold 122 includes an array of liquid inlets 124 that introduce cooling liquid 132 into the vapor chamber 142 in the form of droplets 126. The liquid 132 flows laterally over or through the manifold 122 and into the array of liquid inlets 124. The manifold 122 further includes an array of vapor outlets 130. Vapor 128 created by the evaporation of the droplets 126 travels up through the array of vapor outlet 130 and then exits the cooling assembly 104 as described in more detail below.

Referring once again to FIG. 2, the manifold 122 defines a liquid channel 136 that is fluidly coupled to the inlet port 108. Cooling liquid 132 is received from the inlet port 108 and flows through the liquid channel 136 around posts defining vapor outlets 130, which are described in more detail below. Liquid 132 flowing through the liquid channel 136 enters the liquid inlets 124, such as by capillary suction, to form droplets 126 within the vapor chamber 142. The droplets 126 form between a bottom surface 146 of the manifold 122 and an upper surface 144 of the lower housing 120. A gap H is present between the manifold 122 and the lower housing 120. The bottom surface 146 of the manifold 122 and the upper surface 144 of the lower housing 120 are each hydrophilic surfaces, such as by a hydrophilic coating or layer. The gap H and the hydrophilic surfaces produce droplets 126 having a concave shape.

As stated above, the cooling assembly 104 operates by evaporative cooling. The two parameters that govern evaporative heat flux are the droplet diameter D and the gap H. During operation, the heat generated by the electronic device 116 evaporates the droplets 126, which results in a gradual reduction in the diameter D. If the heat flux is high enough, pinch-off occurs resulting in non-contact of the liquid between the two hydrophilic surfaces. In the event that pinch-off occurs, the cooling assembly 104 still functions as a traditional single or two phase mode cooler without loss of cooling capacity. It is noted that the cooling assembly 104 operates in a constant contact angle mode where the contact angle of the droplets remains constant during the evaporation but the droplet diameter D reduces with heat flux.

The gap H dictates how fast the droplets 126 evaporate. The smaller the gap, the higher the evaporative heat flux. During the evaporation process the droplets 126 exert capillary pressure or suction on the top surface of the manifold 122. Depending on the gap H (e.g., 1 mm - 0.3 mm), a suction pressure within a range of 50 to 100 Pa, including endpoints, is generated. This suction pressure is utilized to pump liquid into the droplets 126 for replenishment to maintain a constant contact angle and continue the evaporation process to achieve higher heat fluxes. As an example, a 68 μL water drop on a hydrophilic surface can remove 80 mW of power from a heated surface, which is twice as much as compared to a hydrophobic surface. Thus, with a 100 x 100 array of liquid droplets a total power about 800 W can be removed. The gap H and droplet diameter D can be tuned to the desired power dissipation of the cooling assembly 104. It is noted that the operation of the cooling assembly 104 is not to evaporate the droplets but to identify critical droplet diameter, at which point liquid is supplied to continuously replenish evaporated droplets 126.

The liquid of the droplets 126 changes phase into a vapor 128 within the vapor chamber 142. This vapor 128 rises and exits the vapor chamber 142 through the array of vapor outlets 130. In the illustrated embodiment the vapor outlets 130 are configured as hollow tubes or posts that route the vapor through the layer of the manifold 122 defining the liquid channel 136 and into the vapor channel 134. In other embodiments, the vapor outlets 130 are not configured as an array but rather as one or more slots around the perimeter of the cooling assembly 104. Thus, vapor 128 is routed to the perimeter of the vapor chamber 142 and then enters the vapor channel 134 through perimeter slots or openings defined by the manifold 122.

The vapor 128 then travels through the vapor channel 134 where it then exits the cooling assembly 104 through the vapor outlet port 138. Although not shown, the vapor 128 is routed to a condenser where it is cooled and returned to a liquid. The liquid and/or vapor may also be routed to a heat exchanger for further cooling. A pump then pumps the liquid back into the cooling assembly 104 through the inlet port 108.

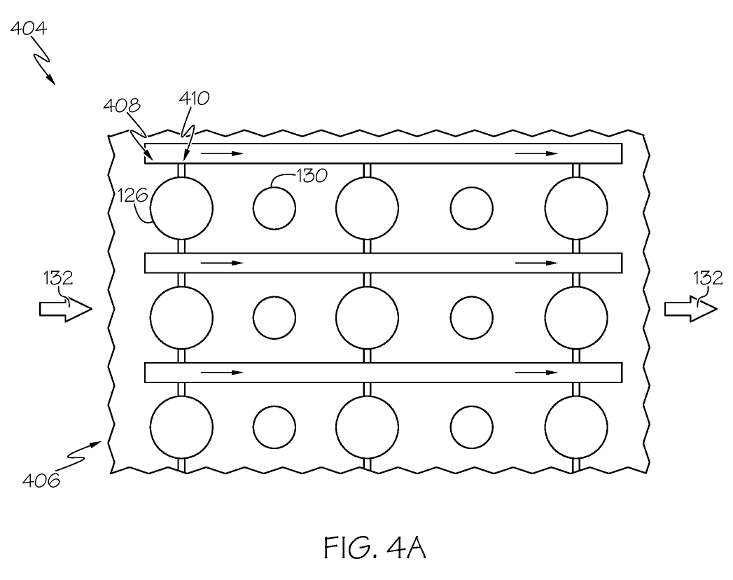

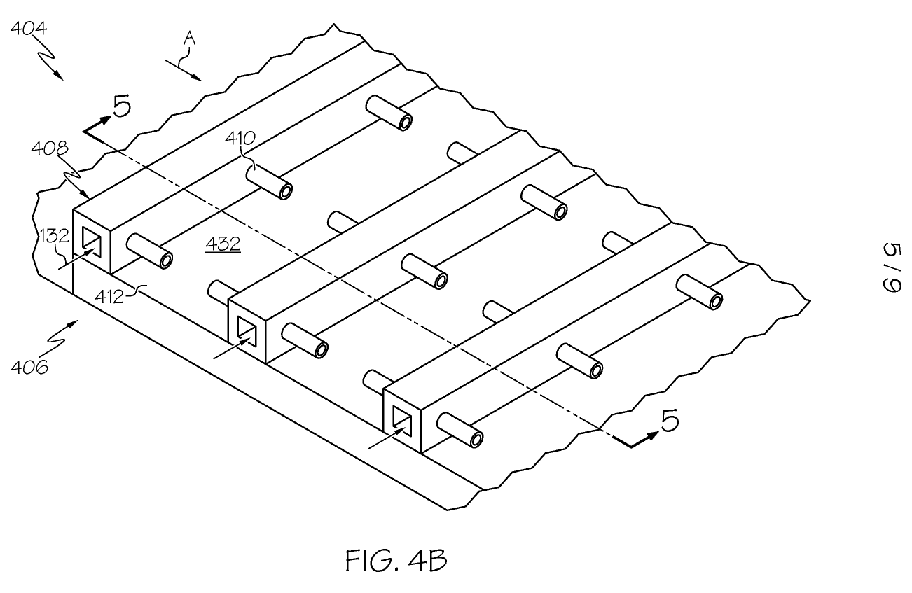

Referring now to FIG. 4A, another example embodiment of a cooling assembly 404 is schematically illustrated in a top view. In this example, the liquid 132 is fed from the side rather than the top as illustrated in FIGS. 2 and 3. The liquid 132 enters the inlet port 108 (FIG. 1) and then a plurality of microchannels 408. Each microchannel 408 includes spatially separated liquid inlets 410 laterally extending therefrom. The liquid flowing within each microchannel 408 exits the liquid inlets 410 to form an array of droplets 126. Bypass liquid 132 that does not become droplets 126 may then exit through the liquid outlet port 112 (FIG. 1) to then be returned to the inlet port 108.

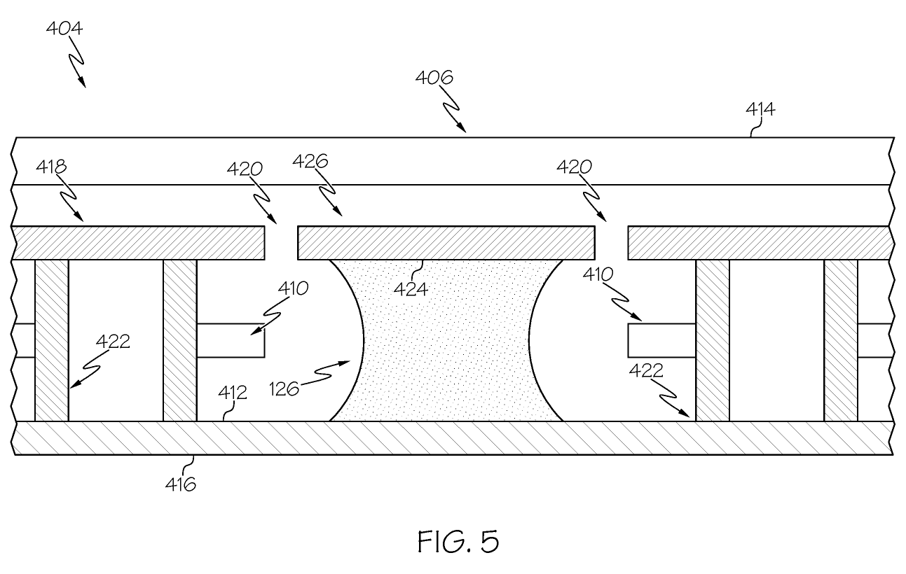

FIG. 4A illustrates a cutaway perspective view of the cooling assembly 404 of FIG. 4A without the manifold and the upper portion of the housing visible. The microchannels 408 extend along a length of the hydrophilic surface 412 of the housing 406. Opposing liquid inlets 410 inject liquid into the vapor chamber 432 from two sides to form an array of droplets 126. The liquid inlets 410 may be tubes as shown in FIG. 4A, or simply openings within the microchannel 408 walls. The hydrophilic surface 424 causes the droplets 126 to form between it and a bottom surface of the manifold 418, which is shown in FIG. 5.

Referring now to FIG. 5, a cross-sectional view of the cooling assembly 404 of FIG. 4B along line 5-5 is shown. The cooling assembly 404 includes a manifold 418 that defines the vapor chamber 432. In the illustrate embodiment, the manifold 418 defines an upper wall of the microchannels 408 to enclose the microchannels 408. However, in other embodiments, the microchannels 408 have a dedicated upper wall (i.e., a ceiling) and the manifold 418 is positioned on top of the upper wall. The manifold 418 also includes an array of vapor outlets 420 configured as openings that allow the vapor to enter a vapor channel 426 where it then flows out of the cooling assembly 404 by way of a vapor outlet port 138 (see FIG. 1). The vapor channel 426 is between an upper surface of the manifold 418 and a lower surface of the upper housing 414. In other embodiments the manifold 418 itself may define an interior vapor channel.

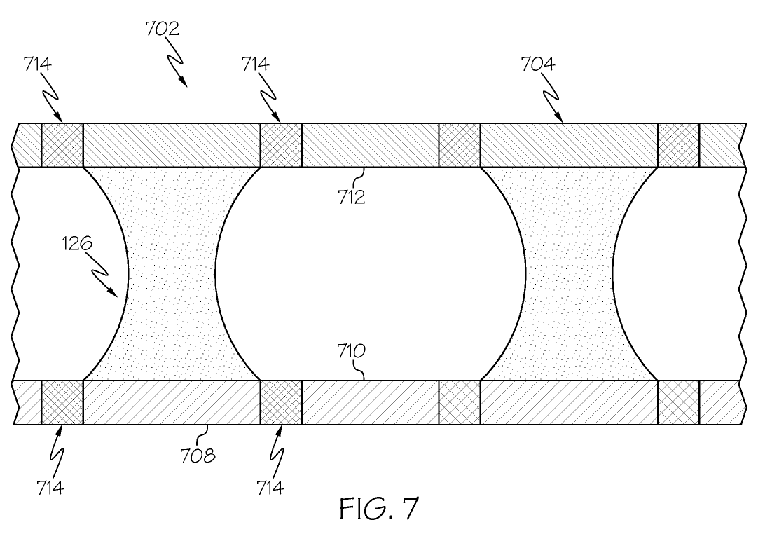

Referring once again to FIG. 4B, in some embodiments the microchannels 408 are configured as plurality of porous strips (which may have a hollow inner channel or not) operable to receive and maintain liquid. The liquid may be introduced into the vapor chamber 432 in the direction indicated by arrow A, which is transverse to the orientation of the plurality of porous strips. The plurality of porous strips may be made of any porous material, such as sintered metal spheres or metal-inverse-opal. The plurality of porous strips maintain a supply of liquid, which is then provided to the hydrophilic surface 412 to form droplets 126. A pattern of hydrophobic regions 714 (see FIG. 7) may be provided to encourage the droplets 126 to form in a desired pattern as desired locations.

Embodiments of the present disclosure may also be configured as passive, closed system vapor chambers that do not utilize external components such as a pump and a condenser. In such embodiments, cooling liquid is evaporated into vapor and condensed back into liquid continuously within the vapor chamber.

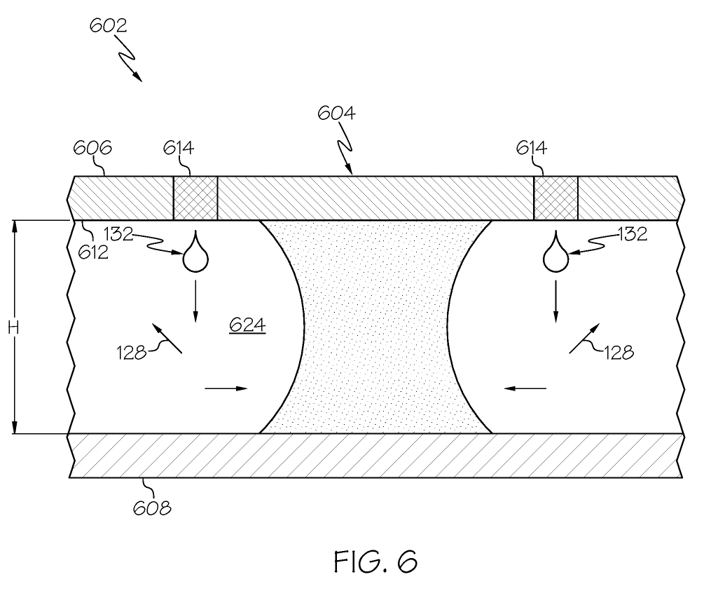

Referring now to FIG. 6, an example cooling assembly 602 having an enclosed passive vapor chamber 624 is illustrated. This example cooling assembly 602 does not have an inlet port, a liquid outlet port, or a vapor outlet port. The housing 604 has an upper housing 606 and a lower housing 608 having an upper hydrophilic surface 612 and a lower hydrophilic surface 610, respectively. Droplets 126 form between the upper hydrophilic surface 612 and the lower hydrophilic surface 610. Heat flux generated by the electronic device (not shown) cause the liquid droplets 126 to evaporate into vapor 128. The upper hydrophilic surface 612 includes an array of hydrophobic region 614 that constrain the upper portion of the droplets 126 and also provide regions for the vapor 128 to condense and, because they are hydrophobic, cause the condensed liquid to drop as returning liquid 132 that falls to the lower hydrophilic surface 610. The returning liquid 132 becomes droplets 126 once again due to the hydrophilic surfaces and the gap H.

FIG. 7 illustrates another passive cooling assembly having a housing 704 with an upper housing 706 defining an upper hydrophilic surface 712 and a lower housing 708 defining a lower hydrophilic surface 710. Droplets 126 are formed between the upper hydrophilic surface 712 and the lower hydrophilic surface 710. In this embodiment, both the upper hydrophilic surface 712 and the lower hydrophilic surface 710 include an array of hydrophobic regions 714 that constrain the droplets 126. The hydrophobic regions 714 on the upper hydrophilic surface 712 cause the liquid 132 to return to the lower hydrophilic surface 710 as described above with respect to FIG. 6. The arrays of hydrophobic regions 714 can be used to increase the droplet volume as the droplets 126 may be arranged closer together.

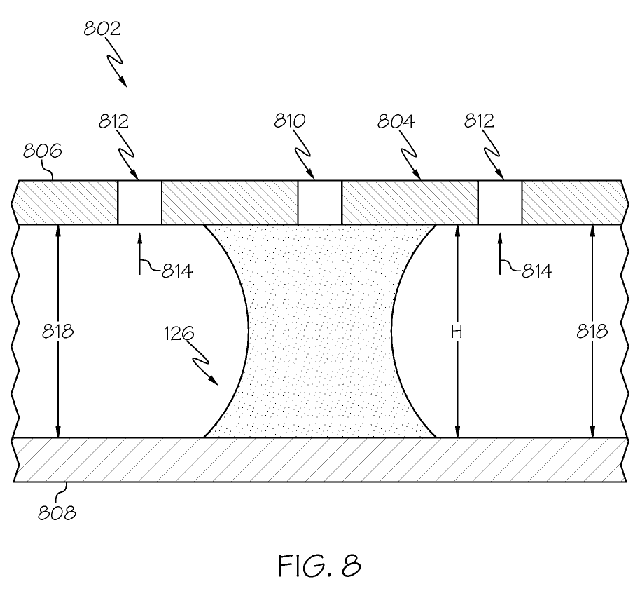

In some embodiments, the gap H may be adjusted to accommodate for non-uniform vapor generation and large droplet volumes depending on the application and desired performance. As stated above, the micro gap H dictates how fast the droplets 126 introduced through inlets 810 evaporate. The gap H may be reduced to increase the evaporative flux 814 through vents 812. As shown in FIG. 8, flexures 818 may be provided between the lower housing 808 and the upper housing 806 (or manifold in some embodiments) that are operable to be controlled to change length. The changing of the length of the flexures 818 adjusts the gap H between the upper housing 808 and the lower housing 808 on demand. Therefore, the performance of the cooling assembly 802 can be tuned in real time to meet cooling demands.

The flexures 818 may be made of any type of suitable material. As a non-limiting example, the flexure 818 may be fabricated from a memory-shape alloy that changes length due to stimuli, such as heat, voltage or light. The material of the flexure 818 may be tuned to adjust its length in response to heat to continuously tune the gap H to provide optimal evaporative flux. The flexures 818 may be used in both the active and passive cooling assembly embodiments.

It should now be understood that embodiments of the present disclosure are directed to evaporative cooling assemblies that utilize to hydrophilic surfaces to maintain an array of liquid droplets. The plurality of liquid inlets introduce liquid into a vapor chamber defined by the two hydrophilic surfaces. One or more vapor outlets are provided to remove vapor due to a phase change of the droplets caused by heat from the heat generating device, such as an electronic device. The liquid may be introduced into the vapor chamber and a top feed configuration where the liquid flows down into the vapor chamber, or a side feed configuration where the liquid travels through micro-channels that is deposited on the hydrophilic surface. The cooling assemblies of the present disclosure may be active in that they pump is utilized to pump cooled liquid into the vapor chamber and a condenser is used to convert vapor into a liquid that is then returned to the vapor chamber by the pump. The cooling assemblies of the present disclosure may also be passive in that the vapor chamber is completely enclosed in vapor is condensed within the vapor chamber itself to continuously supply the droplets. Hydrophobic regions may be patterned on one or more of the hydrophilic surfaces to define the location of the droplets as well as to provide a return of liquid and the passive cooling embodiments. Additionally, flexures may be provided that adjust a gap H of the vapor chamber to continuously tune the performance of the cooling assembly.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

It will be apparent to those skilled in the art that various modifications and variations can be made to the embodiments described herein without departing from the scope of the claimed subject matter. Thus, it is intended that the specification cover the modifications and variations of the various embodiments described herein provided such modification and variations come within the scope of the appended claims and their equivalents.

What is claimed is:

1. A cooling assembly comprising:
a first hydrophilic surface and a second hydrophilic surface;
an array of liquid inlets within one of the first hydrophilic surface and the second hydrophilic surface operable to provide a liquid to form an array of droplets between the first hydrophilic surface and the second hydrophilic surface;
at least one liquid channel fluidly coupled to the array of liquid inlets for providing liquid to the array of liquid inlets;
one or more vapor outlets within the one of the first hydrophilic surface and the second hydrophilic surface operable to receive vapor from between the first hydrophilic surface and the second hydrophilic surface; and
a vapor channel fluidly coupled to the one or more vapor outlets for receiving the vapor from the one or more vapor outlets.

2. The cooling assembly of claim 1, further comprising a housing, a liquid inlet port fluidly coupled to the at least one liquid channel, a liquid outlet port fluidly coupled to the at least one liquid channel, and a vapor outlet port fluidly coupled to the vapor channel.

3. The cooling assembly of claim 1, further comprising a manifold that defines the array of liquid inlets, the one or more vapor outlets, and the one of the first hydrophilic surface and the second hydrophilic surface.

4. The cooling assembly of claim 3, further comprising a housing, wherein the manifold defines the at least one liquid channel, and the vapor channel is between the manifold and the housing.

5. The cooling assembly of claim 3, further comprising a housing, wherein the one or more vapor outlets are defined by an array of hollow posts.

6. The cooling assembly of claim 3, further comprising a plurality of hydrophobic regions on one or more of the first hydrophilic surface and the second hydrophilic surface.

7. The cooling assembly of claim 1, further comprising a plurality of microchannels disposed between the first hydrophilic surface and the second hydrophilic surface, wherein the plurality of microchannels defines the at least one liquid channel and the array of liquid inlets is coupled to the plurality of microchannels.

8. The cooling assembly of claim 7, wherein the plurality of microchannels is fabricated from a porous material.

9. The cooling assembly of claim 1, further comprising one or more flexures operable to adjust a distance between the first hydrophilic surface and the second hydrophilic surface.

10. The cooling assembly of claim 9, wherein the one or more flexures is fabricated from a memory-shape alloy.

11. A cooling assembly comprising:
a housing defining a first hydrophilic surface and a second hydrophilic surface, wherein the housing further defines a vapor chamber;
an array of hydrophobic regions on one or more of the first hydrophilic surface and the second hydrophilic surface, wherein the vapor chamber is operable to be filled with a liquid such that an array of droplets form between the first hydrophilic surface and the second hydrophilic surface, and between the array of hydrophobic regions.

12. The cooling assembly of claim 11, wherein the array of hydrophobic regions is provided on only one of the first hydrophilic surface and the second hydrophilic surface.

13. The cooling assembly of claim 11, further comprising one or more flexures operable to change a distance between the first hydrophilic surface and the second hydrophilic surface.

14. The cooling assembly of claim 11, wherein vapor condenses at the array of hydrophobic regions.

15. A cooling assembly comprising:
a first hydrophilic surface;
a plurality of porous strips provided on the first hydrophilic surface;
a second hydrophilic surface provided proximate a surface of the plurality of porous strips;
an array of hydrophobic regions on at least the second hydrophilic surface;
a liquid inlet port operable to provide liquid between in the first hydrophilic surface and the second hydrophilic surface in a flow path that is transverse to the plurality of porous strips; and
an array of vapor outlets within the second hydrophilic surface; and
a vapor outlet channel fluidly coupled to the array of vapor outlets,
wherein the array of hydrophobic regions cause an array of droplets to form between the first hydrophilic surface and the second hydrophilic surface.

16. The cooling assembly of claim 15, further comprising an array of liquid inlets extending from the plurality of porous strips.

17. The cooling assembly of claim 15, further comprising openings along the plurality of porous strips, wherein the openings define liquid inlets.

18. The cooling assembly of claim 15, wherein the array of hydrophobic regions are on both the second hydrophilic surface and the first hydrophilic surface.

19. The cooling assembly of claim 15, further comprising further comprising one or more flexures operable to change a distance between the first hydrophilic surface and the second hydrophilic surface.

20. The cooling assembly of claim 19, wherein the one or more flexures is fabricated from a memory-shape alloy.
